(19) United States
(12) Patent Application Publication
(10) Pub. No.: US 2026/0025133 A1
(43) Pub. Date: Jan. 22, 2026

(54) SWITCHING CONVERTER RING REDUCTION

(71) Applicant: TEXAS INSTRUMENTS INCORPORATED, Dallas, TX (US)

(72) Inventors: Jinfei SHI, Wuxi (CN); Fangli GE, Shanghai (CN); Luyang HE, Nanjing (CN)

(21) Appl. No.: 18/773,798

(22) Filed: Jul. 16, 2024

(51) Int. Cl. H03K 17/16; H02M 1/32; H02M 3/158

(52) U.S. Cl. CPC H03K 17/162; H02M 3/158; H02M 1/32

(57) ABSTRACT

A circuit includes circuit input and output, first, second and third transistors, a driver circuit, a control circuit, a logic gate, and a capacitor. The driver circuit has a PWM input, and an output coupled to a control terminal of the first transistor. The control circuit has a PWM output coupled to the PWM input, and an enable output. The logic gate has a first input coupled to the circuit input, a second input coupled to the enable output, and a gate output. The second transistor has a first terminal, a second terminal coupled to the circuit output, and a control terminal coupled to the gate output. The third transistor is coupled between the circuit input and the circuit output, and has a control terminal coupled to the first terminal of the second transistor. The capacitor is coupled between the circuit input and the control terminal of the third transistor.

### BACKGROUND

A switching converter is an electronic circuit that converts an input direct current (DC) voltage into one or more DC output voltages that are higher or lower in magnitude than the input DC voltage. A switching converter that generates an output voltage lower than the input voltage is termed a buck or step-down converter. A switching converter that generates an output voltage higher than the input voltage is termed a boost or step-up converter.

Some switching converter topologies include a drive/power switch coupled at a switch node to an energy storage inductor/transformer. Electrical energy is transferred through the energy storage inductor/transformer to a load by alternately opening and closing the switch as a function of a switching signal. The amount of electrical energy transferred to the load is a function of the ON/OFF duty cycle of the switch and the frequency of the switching signal. Switching converters are widely used in electronic devices, particularly battery powered devices, such as portable cellular phones, laptop computers, and other electronic systems in which efficient use of power is desirable.

### SUMMARY

In one example, a circuit includes an input, an output, first, second and third transistors, a driver circuit, a control circuit, a logic gate, and a capacitor. The input is configured to receive a power supply voltage. The output is configured to provide a switching signal. The first transistor has a first terminal, a second terminal coupled to the output, and a control terminal. The driver circuit has a power input coupled to the input of the circuit, a pulse width modulation (PWM) input; and an output coupled to the control terminal of the first transistor. The control circuit has a PWM output coupled to the PWM input of the driver circuit, and an enable output. The logic gate has a first input coupled to the input of the circuit, a second input coupled to the enable output of the control circuit, and an output. The second transistor has a first terminal, a second terminal coupled to the output of the circuit, and a control terminal coupled to the output of the logic gate. The third transistor has a first terminal coupled to the input of the circuit, a second terminal coupled to the output of the circuit, and a control terminal coupled to the first terminal of the second transistor. The capacitor is coupled between the input of the circuit and the control terminal of the third transistor.

In another example, a circuit includes an input, an output, a first transistor, a driver circuit that includes a resistor, and second and third transistors, a fourth transistor, and a capacitor. The input is configured to receive a power supply voltage. The output is configured to provide a switching signal. The first transistor has a first terminal, a second terminal coupled to the output, and a control terminal. The driver circuit has a power input coupled to the input of the circuit, a PWM input; and an output coupled to the control terminal of the first transistor. The second transistor has a first terminal coupled to the input of the circuit, a second terminal coupled to the control terminal of the first transistor, and a control terminal. The third transistor has a first terminal coupled to the second terminal of the second transistor, a second terminal coupled to the output of the circuit, and a control terminal. The resistor is coupled between the control terminal of the second transistor and the control terminal of the third transistor. The fourth transistor has a first terminal coupled to the control terminal of the third transistor, a second terminal coupled to the output of the circuit, and a control terminal. The capacitor is coupled between the input of the circuit and the control terminal of the fourth transistor.

In a further example, a switching converter includes a high-side transistor, a driver circuit, a control circuit, a logic gate, a resistor, a capacitor, a first transistor, and a second transistor. The high-side transistor has a first terminal, a second terminal, and a control terminal. The driver circuit has a power input, a PWM input; and an output coupled to the control terminal. The control circuit has a PWM output coupled to the PWM input of the driver circuit, and an enable output. The logic gate has a first input, a second input coupled to the enable output of the control circuit, and an output. The resistor is coupled between the power input and the first input of the logic gate. The capacitor is coupled between the second terminal of the high-side transistor and the first input of the logic gate. The first transistor has a first terminal, as second terminal coupled to the second terminal of the high-side transistor, and a control terminal coupled to the output of the logic gate. The second transistor has a first terminal coupled to the power input, a second terminal coupled to the second terminal of the high-side transistor, and a control terminal coupled to the first terminal of the second transistor.

### BRIEF DESCRIPTION OF THE DRAWINGS

FIG. 1 is a schematic diagram of an example switching converter that includes a ring control circuit.

FIG. 2 is a schematic diagram of a portion of a switching converter showing detail of example ring control and driver circuits of FIG. 1.

FIGS. 3A and 3B are signal diagrams showing example output signals generated by the control circuit of FIG. 2.

FIG. 4 is a graph of example signals in the switching converter of FIG. 1.

### DETAILED DESCRIPTION

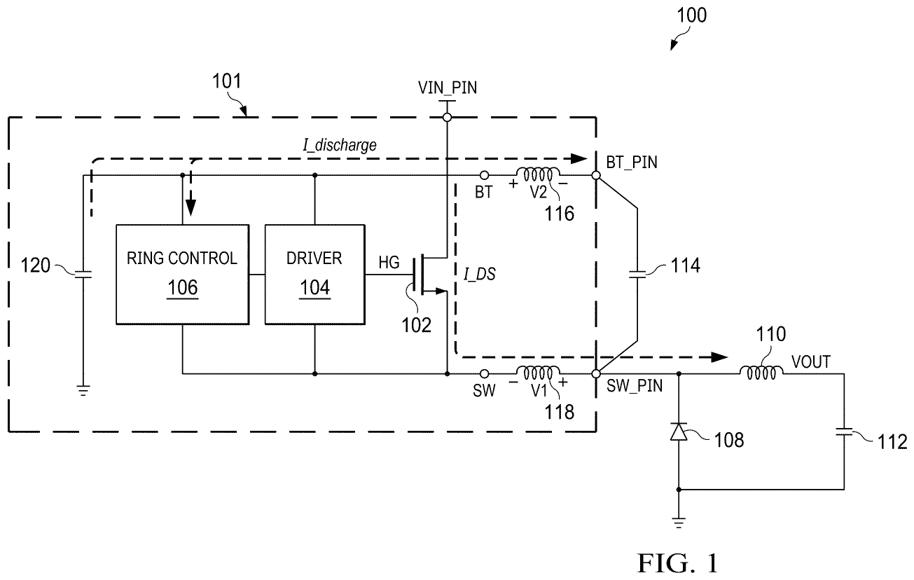

FIG. 1 is a schematic diagram of an example switching converter 100. The switching converter 100 includes a packaged integrated circuit 101, a diode 108, an inductor 110, and capacitors 112, and 114. The packaged integrated circuit 101 includes a high-side transistor 102, a driver circuit 104, and a ring control circuit 106. The high-side transistor 102 may be an n-channel field effect transistor (NFET). The high-side transistor 102 has a first terminal (e.g., drain) coupled to a voltage input terminal (VIN), and a second terminal (e.g., source) coupled to a switching terminal (SW_PIN) of the packaged integrated circuit 101. A control terminal (e.g., gate) of the high-side transistor 102 is coupled to an output of the driver circuit 104. The driver circuit 104 provides a control signal (HG) that turns the high-side transistor 102 on or off. The driver circuit 104 has a power terminal coupled to an input (BT_PIN) of the packaged integrated circuit 101. Voltage for powering the driver circuit 104 may be provided to the packaged integrated circuit 101 via the BT_PIN. The driver circuit 104 has a reference terminal coupled to the SW_PIN and the second terminal of the high-side transistor 102. The capacitor 114 is coupled between the BT_PIN and the SW_PIN.

The diode 108 is coupled between the SW_PIN and a reference terminal (e.g., ground). The diode 108 operates as the low-side switch in the switching converter 100. A first terminal of the inductor 110 is coupled to the cathode of the diode 108. The capacitor 112 is coupled between a second terminal of the inductor 110 and the reference terminal. The output voltage of the 100 is provided at the second terminal of the inductor 110.

The conductors (e.g., bond wires) connecting the die of the packaged integrated circuit 101 to the terminals or pins of the packaged integrated circuit 101 form parasitic inductors 116 and 118. Inductor 116 is coupled between the terminal BT of the die and the BT_PIN. Inductor 118 is coupled between the terminal SW of the die and the SW_PIN. In the die of the packaged integrated circuit 101, a parasitic capacitor 120 is formed between the substrate of the die and a buried layer coupled to the BT. When the high-side transistor 102 is turned off (transitions from on to off), the capacitor 120 is discharged and the current flowing through the inductor 116 and the inductor 118 changes. With the change in current through the inductor 116 and the inductor 118, the voltages across the inductor 116 and the inductor 118 increase and a transient (ringing) is generated across BT and SW. The transient voltage can exceed the safe operating voltage of circuitry coupled to BT and SW, and can damage components of the circuitry. For example, ringing across BT and SW may damage the driver circuit 104.

The ring control circuit 106 reduces the amplitude of transients generated across BT and SW at turn off of the high-side transistor 102 to protect the circuitry of the packaged integrated circuit 101. The ring control circuit 106 has a terminal coupled to the BT and a terminal coupled to the SW. The ring control circuit 106 can detect transients across BT and SW and discharge the capacitor 120 to reduce the change in current flow through the inductor 116, and reduce the transient voltage across the driver circuit 104 and other circuits of the packaged integrated circuit 101. The ring control circuit 106 also has an output coupled to an input of the driver circuit 104. The ring control circuit 106 can provide a control signal at the output during turn off of the high-side transistor 102 if ringing is detected. Responsive to the control signal, the driver circuit 104 can reduce the drive provided to the high-side transistor 102, which can slow the turn off the high-side transistor 102 and reduce the ringing caused by turning off the high-side transistor 102.

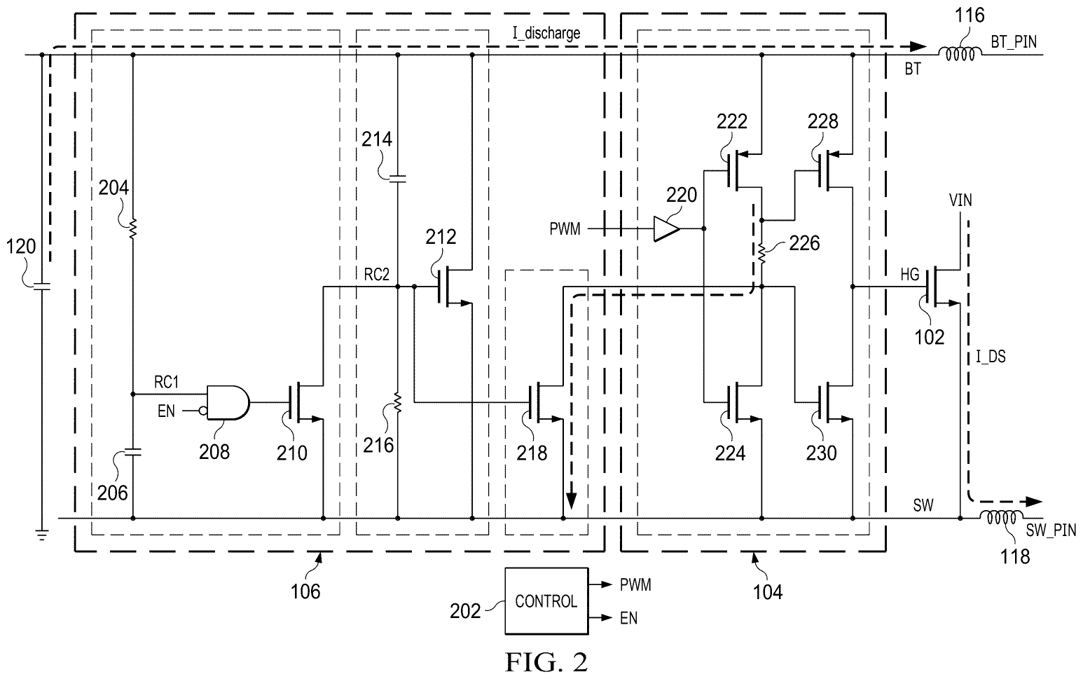

FIG. 2 is a schematic diagram of a portion of the packaged integrated circuit 101 showing detail of the driver circuit 104 and the ring control circuit 106. FIG. 2 also shows a control circuit 202 included in the packaged integrated circuit 101. The control circuit 202 has a pulse width modulation (PWM) output coupled to the driver circuit 104 that provides a signal PWM that turns the high-side transistor 102 on and off, and an output coupled to the ring control circuit 106 that provides a signal EN that triggers transient reduction when the high-side transistor 102 is being turned off.

The driver circuit 104 includes transistors 222, 224, 228, and 230, a resistor 226, and a buffer 220. The transistor 222 and the transistor 228 may be p-channel field effect transistors (PFETs). The transistor 224 and the transistor 230 may be NFETs. The transistor 228 has a first terminal (e.g., source) coupled to BT, a second terminal (e.g., drain) coupled to the control terminal of the high-side transistor 102, and a control terminal. The transistor 230 has a first terminal (e.g., drain) coupled to the control terminal of the high-side transistor 102, a second terminal coupled to SW, and a control terminal. To turn on the high-side transistor 102, the transistor 228 is turned on and the transistor 230 is turned off. To turn off the high-side transistor 102, the transistor 228 is turned off, and the transistor 230 is turned on.

The transistor 222 has a first terminal (e.g., source) coupled to BT, a second terminal (e.g., drain) coupled to the control terminal of the transistor 228, and a control terminal. The transistor 224 has a first terminal (e.g., drain) coupled to the control terminal of the transistor 230, a second terminal coupled to SW, and a control terminal. The resistor 226 is coupled between the second terminal of the transistor 222 and the first terminal of the transistor 224. To turn on the high-side transistor 102, the transistor 224 is turned on and the transistor 222 is turned off. To turn off the high-side transistor 102, the transistor 224 is turned off, and the transistor 222 is turned on.

The buffer 220 has a PWM input coupled to the PWM output of the control circuit 202, and an output coupled to the control terminal of the transistor 222 and the control terminal of the transistor 224. The signal PWM received by the buffer 220 turns the transistors 222, 224, transistor 228, and transistor 230 on and off to control the high-side transistor 102.

The ring control circuit 106 includes transistors 210, 212, and 218, resistors 204 and 216, capacitors 206 and 214, and a logic gate 208. The transistors 210, 212, and 218 may be NFETs. The resistor 204 and the capacitor 206 are coupled in series between BT and SW. A first terminal of the resistor 204 is coupled to BT, and a second terminal of the resistor 204 is coupled to a first terminal of the capacitor 206. A second terminal of the capacitor 206 is coupled to SW. The logic gate 208 has a first input coupled to the second terminal of the resistor 204, and a second input coupled to the EN output of the control circuit 202. An output of the logic gate 208 is coupled to a control terminal (e.g., gate) of the transistor 210. An output signal provided at the output of the logic gate 208 may be a logic high if the signal (RC1) provided at the first input of the logic gate 208 is a logic high, and EN received from the control circuit 202 is a logic low.

The transistor 210 has a first terminal (e.g., drain) coupled to a control terminal (e.g., gate) of the transistor 212, a second terminal coupled to SW. The control terminal of the transistor 210 is coupled to the output of the logic gate 208. The capacitor 214 has a first terminal coupled to the BT, and a second terminal coupled to the first terminal of the transistor 210. The resistor 216 has a first terminal coupled to the second terminal of the capacitor 214, and a second terminal coupled to the SW.

The transistor 212 has a first terminal (e.g., drain) coupled to BT, and a second terminal (e.g., source) coupled to the SW. The control terminal of the transistor 212 is coupled to the first terminal of the transistor 210. The transistor 218 has a first terminal (e.g., drain) that serves as the output of the ring control circuit 106, and is coupled to an input of the driver circuit 104 (e.g., the first terminal of the transistor 224). A second terminal (e.g., source) of the transistor 218 is coupled to SW, and a control terminal (e.g., gate) of the transistor 218 is coupled to the first terminal of the transistor 210.

In operation other than transition of the high-side transistor 102 from on to off, the RC1 signal provided at the first input of the logic gate 208 is a logic high, EN is a logic low, and the output signal of the logic gate 208 is a logic high. Under these conditions, the transistor 210 is turned on (signal RC2 is pulled low), and the transistors 212 and transistor 218 are turned off. If the high-side transistor 102 is transitioning from on to off, EN is a logic high, and the transistor 210 is turned off. With the transistor 210 turned off, a transient present across BT and SW can cause the voltage at the control terminal of the transistor 212 to rise and turn on the transistors 212 and 218. The transistor 212, if turned on, provides a path for discharge of the capacitor 120 and flow of transient current to SW, reducing transient amplitude. The transistor 218, if turned on, draws current through the resistor 226 to slow the turn on the transistor 230 and slow the turn off of the high-side transistor 102, which reduces the generation of transients due to fast turn off of the high-side transistor 102.

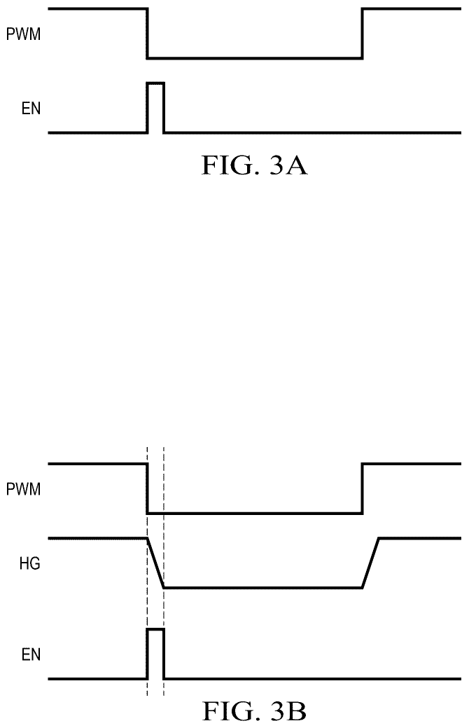

FIGS. 3A and 3B are signal diagrams showing example PWM and EN signals generated by the control circuit 202. If PWM is a logic high, then the driver circuit 104 turns on the high-side transistor 102. If PWM is a logic low, then the driver circuit 104 turns off the high-side transistor 102. At the falling edge of PWM, EN pulses from logic low to logic high. The width or duration of the EN pulses may be fixed (e.g., 10 nanoseconds, 20 nanoseconds, etc.) as shown in FIG. 3A or may be variable based on the control signal HG provided by the driver circuit 104 as shown in FIG. 3B. For example, in FIGS. 3A and 3B, the control circuit 202 may generate the rising edge of EN based on the falling edge of PWM. In FIG. 3A, the control circuit 202 may generate the falling edge of EN a fixed time after the rising edge of EN. In FIG. 3B, the control circuit 202 may generate the falling edge of EN based on HG falling below a selected threshold voltage. Examples of the control circuit 202 may include PWM circuitry to generate PWM, and monostable circuitry to generate EN at the falling edge of PWM.

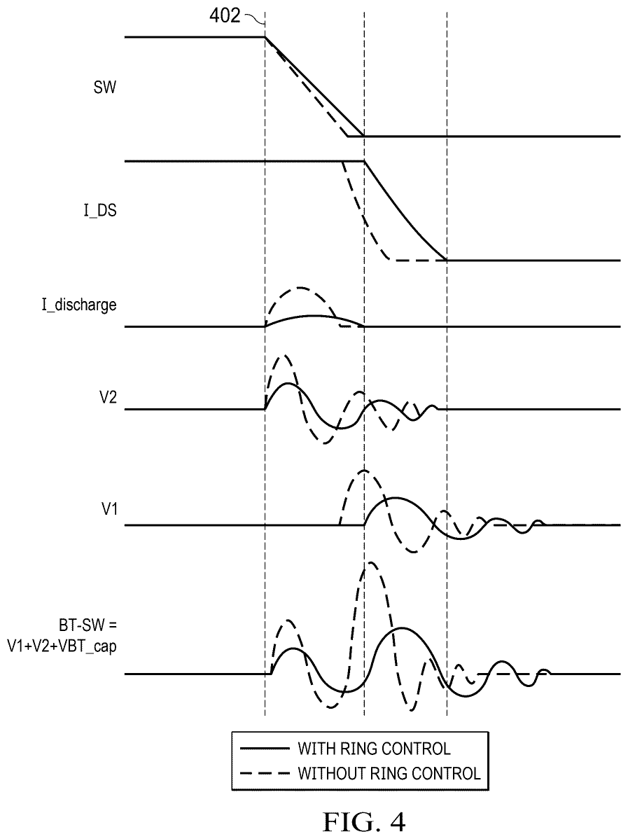

FIG. 4 is a graph of example signals in the packaged integrated circuit 101 as the high-side transistor 102 transitions from on to off with and without the ring control circuit 106. At time 402, the high-side transistor 102 is turning off, and the voltage on SW begins to fall. With the ring control circuit 106, current flow through the transistor 218 slows the turn off of the high-side transistor 102 which slows the fall of the voltage at SW, relative to without the ring control circuit 106. With the reduction of the voltage at SW, the current (I_DS) flowing through the high-side transistor 102 falls. With the ring control circuit 106, the capacitor 120 is discharged through the transistor 212. Accordingly, the current I_discharge flowing from the capacitor 120 to the inductor 116 is reduced with the ring control circuit 106. The voltage V2 across the inductor 116, the voltage V1 across the inductor 118, and the total transient voltage BT-SW is reduced with the ring control circuit 106. Reduction of the transient voltage BT-SW reduces the likelihood of damage to the circuitry of the packaged integrated circuit 101.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
an input configured to receive a power supply voltage;
an output configured to provide a switching signal;
a first transistor having a first terminal, a second terminal coupled to the output, and a control terminal;
a driver circuit having a power input coupled to the input of the circuit, a pulse width modulation (PWM) input; and an output coupled to the control terminal of the first transistor;
a control circuit having a PWM output coupled to the PWM input of the driver circuit, and an enable output;
a logic gate having a first input coupled to the input of the circuit, a second input coupled to the enable output of the control circuit, and an output;
a second transistor having a first terminal, a second terminal coupled to the output of the circuit, and a control terminal coupled to the output of the logic gate;
a third transistor having a first terminal coupled to the input of the circuit, a second terminal coupled to the output of the circuit, and a control terminal coupled to the first terminal of the second transistor; and
a capacitor coupled between the input of the circuit and the control terminal of the third transistor.

2. The circuit of claim 1, further comprising a resistor coupled between the input of the circuit and the first input of the logic gate, and a capacitor coupled between the output of the circuit and the first input of the logic gate.

3. The circuit of claim 1, further comprising a resistor coupled between the control terminal of the third transistor and the output of the circuit.

4. The circuit of claim 1, further comprising a fourth transistor having a first terminal, a second terminal coupled to the output of the circuit, and a control terminal coupled to the first terminal of the second transistor.

5. The circuit of claim 4, wherein the driver circuit includes:
a fifth transistor having a first terminal coupled to the input of the circuit, a second terminal, and a control terminal coupled to the PWM output; and
a sixth transistor having a first terminal coupled to the first terminal of the fourth transistor, a second terminal coupled to the output of the circuit, and a control terminal coupled to the PWM output.

6. The circuit of claim 5, further comprising a resistor coupled between the second terminal of the fifth transistor and the first terminal of the fourth transistor.

7. The circuit of claim 5, wherein the driver circuit includes:
a seventh transistor having a first terminal coupled to the input of the circuit, a second terminal coupled to the control terminal of the first transistor, and a control terminal coupled to the second terminal of the fifth transistor; and
an eighth transistor having a first terminal coupled to the second terminal of the seventh transistor, a second terminal coupled to the output of the circuit, and a control terminal coupled to the first terminal of the sixth transistor.

8. A circuit comprising:
an input configured to receive a power supply voltage;
an output configured to provide a switching signal;
a first transistor having a first terminal, a second terminal coupled to the output, and a control terminal;
a driver circuit having a power input coupled to the input of the circuit, a pulse width modulation (PWM) input; and an output coupled to the control terminal of the first transistor; the driver circuit including:
a second transistor having a first terminal coupled to the input of the circuit, a second terminal coupled to the control terminal of the first transistor, and a control terminal;
a third transistor having a first terminal coupled to the second terminal of the second transistor, a second terminal coupled to the output of the circuit, and a control terminal; and
a resistor coupled between the control terminal of the second transistor and the control terminal of the third transistor;
a fourth transistor having a first terminal coupled to the control terminal of the third transistor, a second terminal coupled to the output of the circuit, and a control terminal; and
a capacitor coupled between the input of the circuit and the control terminal of the fourth transistor.

9. The circuit of claim 8, wherein the driver circuit includes:
a fifth transistor having a first terminal coupled to the input of the circuit, a second terminal coupled to the control terminal of the second transistor, and a control terminal; and
a sixth transistor having a first terminal coupled to the control terminal of the third transistor, a second terminal coupled to the output of the circuit, and a control terminal coupled to the control terminal of the fifth transistor.

10. The circuit of claim 8, further comprising a resistor coupled between the control terminal of the fourth transistor and the output of the circuit.

11. The circuit of claim 8, further comprising a fifth transistor having a first terminal coupled to the input of the circuit, a second terminal coupled to the output of the circuit, and a control terminal coupled to the control terminal of the fourth transistor.

12. The circuit of claim 8, further comprising a fifth transistor having a first terminal coupled to the control terminal of the fourth transistor, a second terminal coupled to the output of the circuit, and a control terminal.

13. The circuit of claim 12, further comprising:
a logic gate having a first input, a second input, and an output coupled to the control terminal of the fifth transistor;
a resistor coupled between the input of the circuit and the first input of the logic gate; and
a capacitor coupled between the output of the circuit and the first input of the logic gate.

14. The circuit of claim 13, further comprising:
a control circuit having a PWM output coupled to the driver circuit; and
an enable output coupled to the second input of the logic gate.

15. A switching converter comprising:
a high-side transistor having a first terminal, a second terminal, and a control terminal;
a driver circuit having a power input, a pulse width modulation (PWM) input; and an output coupled to the control terminal;
a control circuit having a PWM output coupled to the PWM input of the driver circuit, and an enable output;
a logic gate having a first input, a second input coupled to the enable output of the control circuit, and an output;
a resistor coupled between the power input and the first input of the logic gate;
a capacitor coupled between the second terminal of the high-side transistor and the first input of the logic gate;
a first transistor having a first terminal, as second terminal coupled to the second terminal of the high-side transistor, and a control terminal coupled to the output of the logic gate; and
a second transistor having a first terminal coupled to the power input, a second terminal coupled to the second terminal of the high-side transistor, and a control terminal coupled to the first terminal of the second transistor.

16. The switching converter of claim 15, wherein:
the resistor is a first resistor, and the capacitor is a first capacitor; and
the switching converter includes:
a second capacitor coupled between the power input and the control terminal of the second transistor; and
a second resistor coupled between the control terminal of the second transistor and the second terminal of the high-side transistor.

17. The switching converter of claim 15 further comprising a third transistor having a first terminal, a second terminal coupled to the second terminal of the high-side transistor, and a control terminal coupled to the first terminal of the first transistor.

18. The switching converter of claim 17, wherein the driver circuit includes:
a fourth transistor having a first terminal coupled to the power input, a second terminal, and a control terminal coupled to the PWM output; and
a fifth transistor having a first terminal coupled to the first terminal of the third transistor, a second terminal coupled to the second terminal of the high-side transistor, and a control terminal coupled to the PWM output.

19. The switching converter of claim 18, wherein the driver circuit includes a resistor coupled between the second terminal of the fourth transistor and the first terminal of the fifth transistor.

20. The switching converter of claim 18, wherein the driver circuit includes:
a sixth transistor having a first terminal coupled to the power input, a second terminal coupled to the control terminal of the high-side transistor, and a control terminal coupled to the second terminal of the fourth transistor; and
a seventh transistor having a first terminal coupled to the second terminal of the sixth transistor, a second terminal coupled to the second terminal of the high-side transistor, and a control terminal coupled to the first terminal of the fifth transistor.
